(19) United States
(12) Patent Application Publication
(10) Pub. No.: US 2017/0062599 A1
(43) Pub. Date: Mar. 2, 2017

(54) SEMICONDUCTOR CELL

(71) Applicant: HUGA OPTOTECH, INC., Taichung City (TW)

(72) Inventors: Tien-Ching FENG, Taichung City (TW); Tsung-Cheng CHANG, Taichung City (TW)

(21) Appl. No.: 15/246,900

(22) Filed: Aug. 25, 2016

(30) Foreign Application Priority Data
Aug. 28, 2015 (TW) 104128323

(51) Int. Cl. H01L 29/778; H01L 29/04; H01L 29/10; H01L 29/20

(52) U.S. Cl. CPC H01L 29/7786; H01L 29/2003; H01L 29/045; H01L 29/1029

(57) ABSTRACT

A semiconductor cell includes a substrate; a buffer structure disposed on the substrate; a channel layer having a band gap, and including a first portion on the buffer structure and a first protrusion which is disposed on the first portion and has a first top surface and a first inclined surface connecting to the first top surface; a barrier having a band gap greater than the band gap of the channel layer, disposed on the channel layer, and including a second portion disposed on the first portion, and a second protrusion covering the first top surface of the first protrusion and having a second top surface and a second inclined surface connecting to the second top surface and parallel to the first inclined surface; a first electrode disposed on the second protrusion; and a second electrode disposed on the second portion of the barrier and separated from the first electrode.

### REFERENCE TO RELATED APPLICATION

The present application claims the right of priority based on TW application Ser. No. 102122124, filed on Aug. 28, 2015, and the content of which is hereby incorporated by reference in its entirety.

### BACKGROUND OF DISCLOSURE

(a) Field of the Invention

The present application is related to a semiconductor device, and more particularly, to a semiconductor device with a protrusion.

(b) Description of the Prior Art

In recent years, with the growing demand for high power or high frequency products, a semiconductor device made of gallium nitride (GaN) materials like AlGaN/GaN is widely used in power supplies, DC/DC converters, DC/AC inverters, uninterruptible power supplies, vehicles, motors, and wind powers due to its characteristics of high electron mobility and being able to operate at high frequency, high power, and high temperature.

### SUMMARY OF DISCLOSURE

A semiconductor cell includes a substrate; a buffer structure disposed on the substrate; a channel layer having a band gap, disposed on the buffer structure, and including a first portion and a first protrusion, wherein the first protrusion is disposed on the first portion and has a first top surface and a first inclined surface connecting to the first top surface; a barrier having a band gap greater than the band gap of the channel layer, disposed on the channel layer, and including a second portion and a second protrusion, wherein the second portion is disposed on the first portion, the second protrusion covers the first protrusion and has a second top surface and a second inclined surface connecting to the second top surface, and the second inclined surface is parallel to the first inclined surface; a first electrode disposed on the second protrusion; and a second electrode disposed on the second portion of the barrier and separated from the first electrode.

### BRIEF DESCRIPTION OF THE DRAWINGS

The present application is illustrated by way of example and not limited by the figures of the accompanying drawings in which same references indicate similar elements. Many aspects of the disclosure can be better understood with reference to the following drawings. Moreover, in the drawings same reference numerals designate corresponding elements throughout. Wherever possible, the same reference numerals are used throughout the drawings to refer to the same or similar elements of an embodiment.

FIG. 1 shows a top view of a semiconductor device according to a first embodiment of the present application.

FIG. 2A shows a detailed view of a semiconductor cell according to a second embodiment of the present application.

FIG. 2B is a cross-sectional view taken along a sectional line FF′ of the semiconductor cell shown in FIG. 2A.

FIG. 2C is another cross-sectional view taken along the sectional line FF′ of the semiconductor cell shown in FIG. 2A.

FIG. 3A shows a detailed view of a semiconductor cell according to the second embodiment of the present application.

FIG. 3B is a cross-sectional view taken along a sectional line GG′ of the semiconductor cell shown in FIG. 3B.

### DETAILED DESCRIPTION OF THE PREFERRED EMBODIMENTS

In order to make the aforementioned features and advantages of the present application more comprehensible, embodiments accompanying figures are described in details below.

A description accompanied with drawings is provided in the following to explain embodiments of the present application. However, the invention may still be implemented in many other different forms and should not be construed as limited to the embodiments described herein. In the drawings, for the purpose of clarity, the sizes and relative sizes of each layer and region in the drawings may be illustrated in exaggerated proportions.

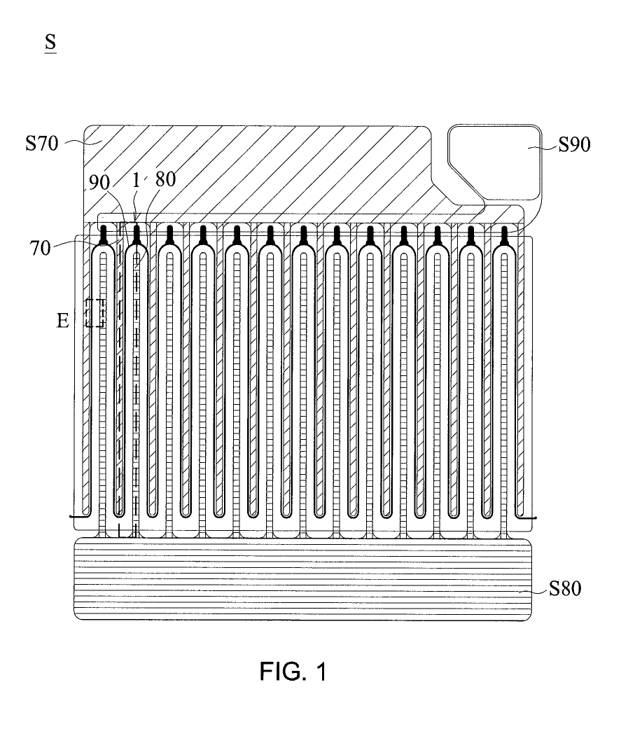

Referring to FIG. 1, FIG. 1 shows a top view of a semiconductor device S according to a first embodiment of the present application. The semiconductor device S, for example a device, includes three terminals. In the embodiment, the semiconductor device S includes a source electrode pad S70, a drain electrode pad S80, a gate electrode pad S90, and at least one semiconductor cell 1. The semiconductor cell 1, for example a field transistor, can be a high electron mobility transistor (HEMT). In the first embodiment, the semiconductor cell 1 includes a semiconductor stack (not shown), a source electrode 70 electrically connects to the source electrode pad S70, a drain electrode 80 electrically connects to the drain electrode pad S80, and a gate electrode 90 electrically connects to the gate electrode pad S90. A material, a position, a layout of the semiconductor stack can be adjusted by the actual request. Additionally, the semiconductor cell 1 of the semiconductor device S can be replaced by the other semiconductor cell in other embodiments.

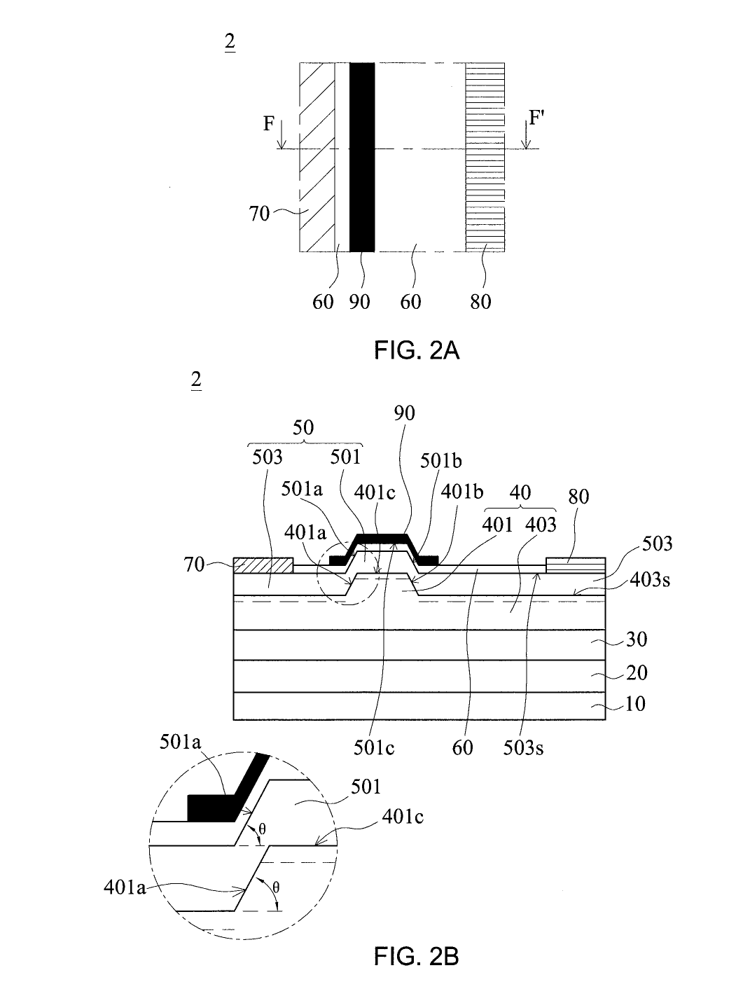

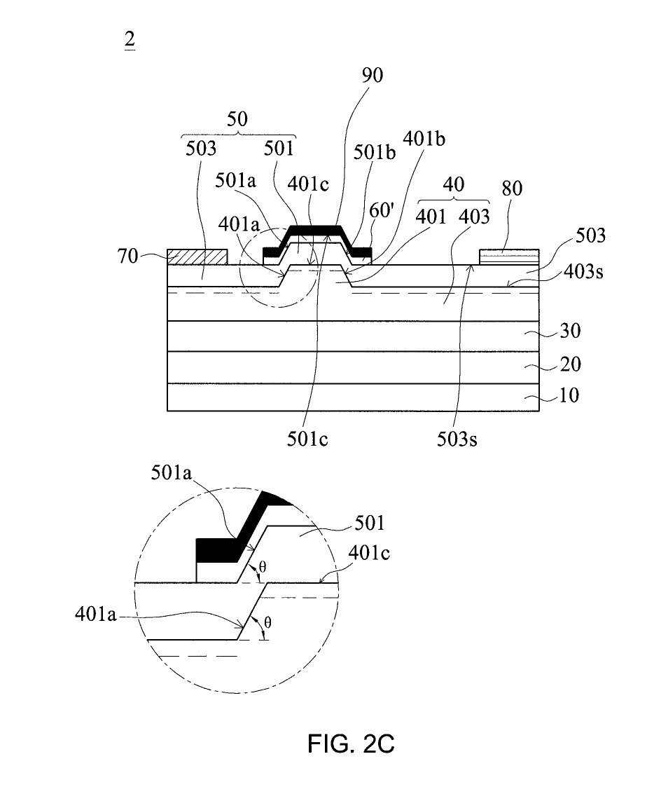

FIGS. 2A and 2B show a semiconductor cell 2 according to a second embodiment of the present application. In the embodiment, the semiconductor cell 2 can replace the semiconductor cell 1 shown in FIG. 1 for forming the semiconductor device S. For clearly reciting details of the semiconductor cell 2, FIG. 2A shows a detailed view of the semiconductor cell 2 and herein a region E is enlarged. Further, FIG. 2B is a cross-sectional view taken along a sectional line FF′ of the semiconductor cell 2 shown in FIG. 2A. The semiconductor cell 2, for example a normally off transistor, includes a substrate 10, a nucleation layer 20, a buffer structure 30, a channel layer 40, a barrier 50, an isolation layer 60, a source electrode 70, a drain electrode 80, and a gate electrode 90. Herein the nucleation layer 20 and the buffer structure 30 are disposed on the substrate 10 sequentially; the channel layer 40 has a band gap and includes a first protrusion 401 and a first portion 403 wherein the first portion 403 is disposed on the buffer structure 30, and the first protrusion 401 is disposed on the first portion 403; the barrier 50 is disposed on the channel layer 40, has a band gap greater than the band gap of the channel layer 40, and includes a second protrusion 501 and a second portion 503 wherein the second protrusion 501 is disposed on the first protrusion 401, and the second portion 503 is disposed on the first portion 403 and between the first protrusion 401 and the second protrusion 501; the isolation layer 60 is disposed on the barrier 50; the gate electrode 90 is disposed on the second protrusion 501; the source electrode 70 and the drain electrode 80 are disposed on the second portion 503 and separated from the gate electrode 90.

While manufacturing the semiconductor cell 2, firstly the substrate 10 is provided. The substrate 10 can be a silicon substrate with a thickness of 600˜1500 μm. A material of the substrate 10 can include a semiconductor material like silicon, silicon carbide, gallium nitride, or oxide material like sapphire. Dopants can be doped in the substrate 10 so as to form a conductive substrate or insulated substrate. Taking the silicon substrate for example, boron or magnesium can be dopants.

Sequentially, the nucleation layer 20 is epitaxially grown on a (111) plane of the substrate 10 along a {0001} direction by growth method, such as metal-organic chemical vapor deposition (MOCVD) or molecular-beam epitaxy (MBE). Herein, a thickness of the nucleation layer 20 is in a range between 20 nm and 200 nm. With the nucleation layer 20, epitaxial qualities of the buffer structure 30 and the channel layer 40 formed on the nucleation layer 20 can be improved. The nucleation layer 20 can include an IIIA-VA semiconductor material such as aluminum nitride, gallium nitride, or aluminum gallium nitride.

After the nucleation layer 20 is formed, the buffer structure 30 is epitaxially grown on the nucleation layer 20. The buffer structure 30 is applied for improving the epitaxial qualities of the channel layer 40 and the barrier 50 formed thereon and has a thickness of 1 μm˜10 μm. The buffer structure 30 can include a single layer or multiple layers. As the buffer structure 30 includes multiple layers, the multiple layers can be a superlattice stack or a stack having two or more than two layers made of different materials. The buffer structure 30 with a single layer or multiple layers can include a group IIIA-VA material and other elements while the IIIA-VA material can be aluminum nitride, gallium nitride, or aluminum gallium nitride, and the element can be carbon or iron doped in the buffer structure 30 with fixed concentration or grading concentration varying along a growth direction. Additionally, as the buffer structure 30 includes a superlattice stack, the buffer structure 30 can include two layers stacked repeatedly with different materials including group IIIA-VA semiconductor materials. For example, the two layers can be an aluminum layer and an aluminum gallium layer, a thickness of the aluminum layer and the aluminum gallium layer can be 2 nm˜30 nm, and a whole thickness of the buffer structure 30 can be 1 μm˜5 μm.

After forming the buffer structure 30, the channel layer 40 is epitaxially grown on the buffer structure 30. The channel layer 40 includes the firs protrusion 401 and the first portion 403. When forming the channel layer 40, the first portion 403 of the channel layer 40 is formed by growing a substantially uniform indium gallium nitride layer (InₓGa₍₁₋ₓ₎N, wherein 0≦×<1) of a thickness 50 nm˜300 nm on the buffer structure 30. Next, a mask, for example a SiNₓ mask, covers a portion of a surface 403s of the first portion 403, and then the first protrusion 401 of the channel layer 40 is formed on the uncovered surface 403s by regrowing the indium gallium nitride layer. Afterwards, the mask is removed after forming the first protrusion 401. Nerveless, the invention is not limited hereto. In other embodiment, an indium gallium nitride layer of a thicker thickness can be formed, and then the first protrusion 401 and first portion 403 are formed by removing a portion of the indium gallium nitride layer. In the embodiment, the first protrusion 401 includes a first inclined surface 401a, a third inclined surface 401b, and a first top surface 401c. Herein, the first inclined surface 401a and the third inclined surface 401b connect to the first top surface 401c, and a position of the first top surface 401c of the first protrusion 401 is higher than a position of the surface 403s of the first portion 403. Additionally, the first inclined surface 401a and the third inclined surface 401b can be crystalline planes. In the embodiment, crystalline directions of the first inclined surface 401a and the third inclined surface 401b can be {11̅01} and an included angle between the first inclined surface 401a or the third inclined surface 401b and the surface 403s can be 61.9 degrees. In other embodiment, the crystalline directions of the first inclined surface 401a and the third inclined surface 401b can be {112̅2}. An included angle between the first inclined surface 401a and the surface 403s, or an included angle between the third inclined surface 401b and the surface 403s can be 58.9 degrees. However, the invention is not limited to the angles or crystalline directions mentioned above, and the included angles and crystalline directions can be different in another embodiment.

After forming the channel layer 40, the barrier 50 is epitaxially grown on the channel layer 40. The barrier 50 includes the second protrusion 501 disposed on the first protrusion 401 and the second portion 503 disposed on the first portion 403. In the embodiment, because the barrier 50 is grown on the channel layer 40 which no mask covers on, the barrier 50 can be directly formed on the surface 403s and also on the first inclined surface 401a, the third inclined surface 401b, and the first top surface 401c of the first protrusion 401. Herein, the second portion 503 is formed on the surface 403s and a portion of the first inclined surface 401a and a portion of the third inclined surface 401b, and the second protrusion 501 is formed on the first top surface 401c and another portion of the first inclined surface 401a and another portion of the third inclined surface 401b. A second top surface 501c of the second protrusion 501 is located higher than a surface 503s of the second portion 503, and the second protrusion 501 substantially covers the first top surface 401c of the first protrusion 401 and is aligned with the first protrusion 401. The second protrusion 501 includes a second inclined surface 501a, a fourth inclined surface 501b, and the second top surface 501c. Herein the second inclined surface 501a and the fourth inclined surface 501b connect to the second top surface 501c and are parallel to the first inclined surface 401a and the third inclined surface 401b respectively. Herein, a shortest distance between the first inclined surface 401a and the second inclined surface 501a is smaller than or equal to a shortest distance between the first top surface 401c and the second top surface 501c; a shortest distance between the third inclined surface 401b and the fourth inclined surface 501b is smaller than or equal to a shortest distance between the first top surface 401c and the second top surface 501c. Additionally, the second inclined surface 501a and the fourth inclined surface 501b can be crystalline planes. In the embodiment, crystalline directions of the second inclined surface 501a and the fourth inclined surface 501b can be {11̅01}. An included angle between the second inclined surface 501a and the surface 503s can be 61.9 degrees and an included angle between the fourth inclined surface 501b and the surface 503s can be 61.9 degrees. In other embedment, crystalline directions of the second inclined surface 501a and the fourth inclined surface 501b can be {112̅2}. An included angle between the second inclined surface 501a and the surface 503s can be 58.9 degrees and an included angle between the fourth inclined surface 501b and the surface 503s can be 58.9 degrees. However, the invention is not limited hereto. In other embodiment, the first inclined surface 401a, the second inclined surface 501a, the third inclined surface 401b, and the fourth inclined surface 501b can be the same crystalline surface, and crystalline directions of the first inclined surface 401a, the second inclined surface 501a, the third inclined surface 401b, and the fourth inclined surface 501b can be the same, for example, {11̅01} or {112̅2}.

Additionally, the invention is not limited to the angles mentioned above and an included angle between an inclined surface and a surface of a first portion can be different from 61.9 degrees or 58.9 degrees.

In the embodiment, a thickness of the barrier 50 can be between 20 nm and 50 nm, the band gap of the barrier 50 is greater than the band gap of the channel layer 40, and a lattice constant of the barrier 50 is smaller than that of the channel layer 40. A material of the barrier 50 can be aluminum gallium nitride (AlₓGa₍₁₋ₓ₎N, wherein x is between 0.1 and 0.3). The channel layer 40 and the barrier 50 can be intrinsic semiconductors. In other embodiment, a material of the barrier 50 can be aluminum gallium indium nitride (Al_{y}In_{z}Ga_{(1-z)}N, wherein 0<y<1, and 0<z<1). Since the barrier 50 has a property of spontaneous polarization, and a piezoelectric polarization is formed between the channel layer 40 and the barrier 50 due to a lattice constant mismatch, a two-dimensional electron gas (depicted as dashed lines) is formed near an interface between the channel layer 40 and the barrier 50. Because the semiconductor cell 2 of the embodiment can be a normally off transistor, as shown in FIG. 2A and FIG. 2B, when no voltage is applied, the two-dimensional electron gas is discontinuously formed near the interface between the channel layer 40 and the barrier 50. Specifically, the two-dimensional electron gas (depicted as dashed lines) is formed in the channel layer 40 and near the top surface 401 and/or an interface between the first portion 403 and the second portion 503, but the two-dimensional electron gas is not formed near the first inclined surface 401a and the third inclined surface 401b. In order to discontinuously form the two-dimensional electron gas, in the present embodiment, by controlling grades of the first inclined surface 401a and the second inclined surface 501a and/or by controlling grades of the third inclined surface 401b and the fourth inclined surface 501b, the first inclined surface 401a and the second inclined surface 501a, and/or the third inclined surface 401b and the fourth inclined surface 501b are not parallel to the surface 403s. Thereby, the piezoelectric polarization effect on the first inclined surface 401a and/or the third inclined surface 401b, which is caused by a lattice constant mismatch between the channel layer 40 and the barrier 50, can be reduced, and thus the two-dimensional electron gas is not formed there.

After forming the barrier 50, the isolation layer 60 can be formed on the barrier 50 by epitaxial growth or sputtering deposition. To be more specific, the growth method can be metal-organic chemical vapor deposition (MOCVD) or molecular-beam (MBE). In the embodiment, the isolation layer 60 substantially covers a surface of the barrier 50 for reducing surface leakage current and protecting the surface of the barrier 50. The isolation layer 60 can be an insulated material or a high-resistance material and includes a nitride base insulated material like silicon nitride (SiNₓ), an oxide insulated material like silicon oxide, or a p-type IIIA-VA semiconductor like p-type gallium nitride (p-GaN). The invention is not limited hereto and the material mentioned above can be replaced by other materials. Additionally, a position of the isolation layer 60 is not limited by the disclosure of the application. In FIG. 2C, the isolation layer 60 in FIG. 2B can be replaced by an isolation layer 60′ which substantially covers the second top surface 501c of the second protrusion 501, the second inclined surface 501a, and the fourth inclined surface 501b. A material of the isolation layer 60′ can be p-GaN with high resistance, and a band gap of the isolation layer 60′ is smaller than the band gap of the barrier 50, so as to prevent surface leakage current and protect the surface of the barrier 50.

After forming the isolation layer 60, the source electrode 70, the drain electrode 80, and the gate electrode 90 are formed on the barrier 50 and functioned as terminals electrically connecting to an external device. Herein, the source electrode 70, the drain electrode 80 are disposed on the surface 503s of the second portion 503 respectively. The gate electrode 90 is disposed on the second protrusion 501 of the barrier 50 and on the isolation layer 60, and is disposed between the source electrode 70 and the drain electrode 80. The source electrode 70, the drain electrode 80, and the gate electrode 90 are separated from one another. In the embodiment, by properly selecting suitable materials for the source electrode 70 and the drain electrode 80 and/or by a process like annealing, an ohmic contact between the drain electrode 80 and the barrier 50 or between the source electrode 70 and the barrier 50 is formed. Similarly, by properly selecting a material for the gate electrode 90, a schottky contact between the gate electrode 90 and the barrier 50 is formed. Materials of the source electrode 70 and the drain electrode 80 can be metal like titanium, aluminum, and a material of the gate electrode 90 can be metal like nickel, gold, tungsten, and titanium nitride.

After forming the source electrode 70, the drain electrode 80, and the gate electrode 90, a second isolation layer (not shown) can be formed to cover surfaces of the barrier 50, the isolation layer 60, the source electrode 70, the drain electrode 80 and the gate electrode 90 to prevent the electrical properties of the semiconductor device S from being impacted by moisture. In the embodiment, the second isolation layer can be etched so that portions of surfaces of the source electrode 70, the drain electrode 80 and the gate electrode 90 are exposed, and the semiconductor cell 2 electrically connects to an external device by the exposed portions. Materials and functions of the second isolation layer of the embodiment are similar to the isolation layer 60/60′, and descriptions of the second isolation layer can refer to the above descriptions.

After completely manufacturing the semiconductor cell 2 of the embodiment, the semiconductor cell 2 can be turned on by applying a positive voltage greater than a turn-on voltage on the gate electrode 90. A magnitude of the turn-on voltage is related to materials and thicknesses of the barrier 50 and the isolation layer 60/60′. For example, when a thickness of the barrier 50 is about 25 nm and a material of the barrier 50 includes Al_{0.2}Ga_{0.8}N, the turn-on voltage is about 1V.

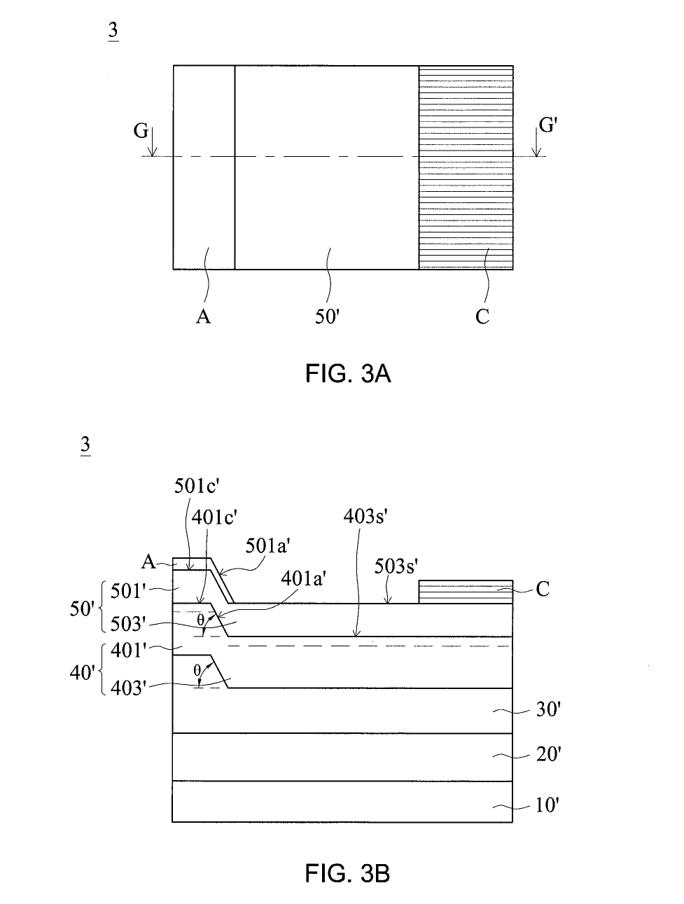

In the embodiment, in addition to being a device with three terminals, the semiconductor device S can be a device with two terminals, for example, a schottky diode. A semiconductor device with two terminals can include an anode pad, a cathode pad, and multiple semiconductor cells with two terminals individually electrically connecting to the anode pad and the cathode pad. Please refer to FIG. 3A and FIG. 3B. FIG. 3A shows an enlarged view of the semiconductor cell 3 in accordance with a third embodiment of the application. FIG. 3B shows a cross-sectional view along a sectional line GG' as shown in FIG. 3A. In the embodiment, the semiconductor cell 3 can include two terminals. For example, the semiconductor cell 3 can be a schottky diode and include a substrate 10′, a nucleation layer 20′, a buffer structure 30′, a channel layer 40′, a barrier 50′, an anode A, and a cathode C.

A method for manufacturing the semiconductor cell 3 is similar to that of the semiconductor cell 2. Firstly, the substrate 10′ is provided. Then, the nucleation layer 20′, the buffer structure 30′, the channel layer 40′, and the barrier 50′ are epitaxially grown on the substrate 10′ in sequence. Herein, descriptions about materials, thicknesses, and functions of the substrate 10′, the nucleation layer 20′, and the buffer structure 30′ can refer to the corresponding descriptions of the second embodiment.

While forming the channel layer 40′, a first portion 403′ of the channel layer 40′ is formed by growing a substantially uniform indium gallium nitride layer (InₓGa₍₁₋ₓ₎N, where 0≦×<1) of a thickness 50 nm ˜300 nm on the buffer structure 30. Next, a mask, for example, a SiNₓ mask, covers a portion of a surface 403s′ of the first portion 403′, and then a first protrusion 401′ of the channel layer 40′ is formed on the uncovered surface 403s′ of the first portion 403′ by regrowing the indium gallium nitride layer. In another embodiment, a channel layer of a thicker thickness can be formed, and then a first protrusion and a first portion are formed by removing portions of the channel layer. In the embodiment, the first protrusion 401′ includes a first inclined surface 401a′ and a first top surface 401c′. Herein, the first inclined surface 401a′ connects to the first top surface 401c′. Additionally, the first inclined surface 401a′ can be a crystalline plane. In the embodiment, a crystalline direction of the first inclined surface 401a′ can be {11̅01} and an included angle between the first inclined surface 401a′ and the surface 403s′ can be 61.9 degrees. In other embodiment, the crystalline direction of the first inclined surface 401a′ can be {b 112̅2} and an included angle between the first inclined surface 401a′ and the surface 403s′ can be 58.9 degrees.

After forming the channel layer 40′, the barrier 50′ is also epitaxially grown on the channel layer 40′. The barrier 50′ includes a second protrusion 501′ disposed on the first protrusion 401′ and a second portion 503′ disposed on the surface 403s′ of the first portion 403′. The second protrusion 501′ substantially covers the first protrusion 401′ and has a second inclined surface 501a′ and a second top surface 501c′ connecting to the second inclined surface 501a′. Further, the second inclined surface 501a′ can be a crystalline plane. In the present embodiment, a crystalline direction of the second inclined surface 501a′ can be {11̅01} and an included angle between the second inclined surface 501a′ and a surface 503s′ can be 61.9 degrees, or a crystalline direction of the second inclined surface 501a′ can be {112̅2} and an included angle of the second inclined surface 501a′ and the surface 503s′ can be 58.9 degrees. However, the present application is not limited to the angle mentioned above. In other embodiment, it can be of different angles. A thickness of the barrier 50′ can be in the range of about 20 nm˜50 nm, the barrier 50′ has a band gap greater than a band gap of the channel layer 40′, and a lattice constant of the barrier 50′ is smaller than that of the channel layer 40′. In the embedment, the barrier 50′ can be an aluminum gallium nitride layer (AlₓGa₍₁₋ₓ₎N, wherein x is between 0.1 and 0.3), and the channel layer 40′ and the barrier 50′ can be intrinsic semiconductors; in other embodiments, a material of the barrier can include an aluminum indium gallium nitride (Al_{y}In_{z}Ga_{(1-z)}N, wherein 0< y<1 and 0≦ z<1). In addition, due to an interaction between a spontaneous polarization caused by the barrier 50′ itself and a piezoelectric polarization caused by a lattice constant mismatch between the channel layer 40′ and the barrier 50′, a two-dimensional electron gas (depicted as dashed lines in the figure) is formed near an interface between the channel layer 40′ and the barrier 50′.

In the embodiment, in order to turn off the semiconductor cell 3 under a condition of no voltage being applied, the two dimensional gas is discontinuously formed in an interface between the channel layer 40 and the barrier 50. To be more specific, the two dimensional electron gas (depicted as dashed lines) is formed in the channel layer 40′ and near the first top surface 401c′ and an interface between the first portion 403′ and the second portion 503′, but not formed near the first inclined surface 401a′. In order to discontinuously form the two dimensional electron gas, in the embodiment, the first inclined surface 401a′ and the second inclined surface 501a′ are not parallel to the surface 403s′ by controlling grades of the first inclined surface 401a′ and the second inclined surface 501a′, so that the piezoelectric polarization effect on the first inclined surface 401a′, which is caused by lattice constant mismatch between the channel layer 40′ and the barrier 50′, can be reduced, and the two dimensional electron gas is not formed there.

After forming the barrier 50′, the anode A and the cathode C are formed on the barrier 50′. Herein the anode A is formed on the second protrusion 501′ of the barrier 50′, and the cathode C is formed on the surface 503s′ of the second portion 503′ of the barrier 50′. When forming the anode A, a suitable metal with high work function is selected as the material of the anode A so that a schottky contact is formed between the anode A and the barrier 50′. When forming the cathode C, another suitable metal is selected as the material of the cathode C and/or an annealing process is proceed so that an ohmic contact is formed between the barrier 50′ and the cathode C. However, the invention is not limited herein.

After forming the anode A and the cathode C, a second isolation layer (not shown) is formed to cover surfaces of the barrier 50′, the anode A, and the cathode C so as to prevent the semiconductor cell 3 from deteriorating and to prevent electrical properties of the semiconductor cell 3 being impacted by moisture. In the embodiment, descriptions about a material of the second isolation layer can refer to the prior paragraphs and they are omitted herein. Similar to the second embodiment, the second isolation layer in the embodiment can be further etched to expose portions of the anode A and cathode C so as to electrically connect to an external device. In the embodiment, when a positive voltage greater than a turn-on voltage is applied to the anode A of the semiconductor cell 3, the semiconductor cell 3 turns on. Moreover, the turn-on voltage can be adjusted by the material and thickness of the barrier 50′.

It is believed that the present embodiments and their advantages will be understood from the foregoing description, and it will be apparent that various changes may be made thereto without departing from the spirit and scope of the embodiments or sacrificing all of its material advantages.

What is claimed is:

1. A semiconductor cell comprising:
a substrate;
a buffer structure disposed on the substrate;
a channel layer having a band gap, and comprising a first portion and a first protrusion wherein the first portion is disposed on the buffer structure, and the first protrusion is disposed on the first portion and has a first top surface and a first inclined surface connecting to the first top surface;
a barrier having a band gap greater than the band gap of the channel layer, disposed on the channel layer, and comprising a second portion and a second protrusion wherein the second portion is disposed on the first portion, the second protrusion covers the first top surface of the first protrusion and has a second top surface and a second inclined surface connecting to the second top surface, and the second inclined surface is parallel to the first inclined surface;
a first electrode disposed on the second protrusion; and
a second electrode disposed on the second portion of the barrier and separated from the first electrode.

2. The semiconductor cell as claimed in claim 1, wherein a two dimensional electron gas is formed in the channel layer and near the top surface and/or an interface between the first portion and the second portion.

3. The semiconductor cell as claimed in claim 1, wherein a material of the channel layer comprises GaN, and a material of the barrier comprises AlₓGa₁₋ₓN wherein 0.2<×<0.3.

4. The semiconductor cell as claimed in claim 3, wherein a shortest distance between the first inclined surface and the second inclined surface is smaller than or equal to a shortest distance between the first top surface and the second top surface.

5. The semiconductor cell as claimed in claim 1, wherein the first inclined surface is a crystalline plane, and a crystalline direction of the first inclined surface comprises {11̅01} or {112̅2}, or an included angle between the first inclined surface and a surface of the first portion is 61.9 degrees or 58.9 degrees.

6. The semiconductor cell as claimed in claim 5, wherein the first protrusion further comprises a third inclined surface, the second protrusion further comprises a fourth inclined surface, the third inclined surface is parallel to the fourth inclined surface, and a shortest distance between the third inclined surface and the fourth inclined surface is smaller than or equal to a shortest distance between the first top surface and the second top surface.

7. The semiconductor cell as claimed in claim 6, wherein the third inclined surface is a crystalline plane, and a crystalline direction of the third inclined surface is the same as the crystalline direction of the first inclined surface.

8. The semiconductor cell as claimed in claim 1, further comprising a third electrode, wherein the first electrode is a gate electrode, the second electrode is a source electrode, the third electrode is a drain electrode, and the first electrode is disposed between the second electrode and the third electrode.

9. The semiconductor cell as claimed in claim 8, further comprising a p type semiconductor layer disposed between the third electrode and the second protrusion wherein the p type semiconductor layer has a band gap, and a band gap of the p type semiconductor layer is smaller than the band gap of the barrier.

10. The semiconductor cell as claimed in claim 1, wherein the first electrode is an anode and the second electrode is a cathode.
